(19) United States
(12) Patent Application Publication
(10) Pub. No.: US 2002/0117395 A1
(43) Pub. Date: Aug. 29, 2002

(54) Shutter rotation device

(75) Inventors: Muh-Lang Jang, Miaoli Hsien (TW); Hua-Jen Tseng, Hsinchu Hsien (TW); Chun-Chieh Lee, Hsinchu Hsien (TW); Hung-Lin Ke, Hsinchu (TW)

Correspondence Address: DARBY & DARBY P.C., 805 Third Avenue, New York, NY, 10022, US

(73) Assignee: Mosel Vitelic Inc.

(21) Appl. No.: 09/841,566

(22) Filed: Apr. 19, 2001

(30) Foreign Application Priority Data
Feb. 13, 2001 (TW) 90202157

(51) Int. Cl. C23C 14/00; C23C 16/00

(52) U.S. Cl. 204/298.11; 118/723 EB; 118/723 VE

(57) ABSTRACT

A shutter rotation device is provided. The shutter rotation device is adapted for use with an electric beam evaporator, and it comprises a rotation mechanism and a fixed member. The fixed member connects a frame of the electric beam evaporator to the rotation mechanism. By means of adding the fixed member, the shutter of the shutter rotation device can be prevented from shifting. Therefore, the position of a vacuum seal on the shutter rotation device can be maintained, and the vacuum maintains its integrity.

### BACKGROUND OF THE INVENTION

1. Field of the Invention

The invention relates to a shutter rotation device; in particular, the invention relates to a shutter rotation device that prevents its shutter from shifting.

2. Description of the Related Art

In the development of the semiconductor process, main techniques of physical vapor deposition are evaporation deposition and sputtering. Evaporation deposition is a technique that deposits a film on an object by bringing a source containing deposition material to a high temperature.

FIG. 1 is a diagram showing an electron beam evaporator 10. The electric beam evaporator 10 comprises an evaporation chamber 11 for processing vacuum evaporation deposition and a vacuum system 17 for providing the desired vacuum condition during the evaporation deposition. In the evaporation chamber 11, solid deposition material (hereinafter referred to as the source 15) is disposed in a crucible 14. An electric beam 16 is used to heat the source 15. The source 15 is continuously heated until its temperature approaches melting point. At this time, the evaporation capability of the source 15 is very strong. Using atoms evaporating from the source 15, a film is deposited on a wafer 13 located on a wafer chuck 12 beyond the source 15.

Referring to FIG. 2, a shutter rotation device 18 is disposed inside the evaporation chamber 11, and used to cover the crucible 14. When the source 15 is pre-melted, it can be covered by a shutter 181 of the shutter rotation device 18. Therefore, the particles, produced during the pre-melting of the source 15, can be prevented from ascending with the vapor, produced during the pre-melting of the source 15, and forming a film on the wafer 13. If the particles are deposited on the wafer 13, the thickness of the film on the wafer 13 may be uneven.

As shown in FIG. 2, the shutter rotation device 18 is provided with a rotation mechanism 190 in normal atmospheric pressure, and it is provided with a shaft 183 and the shutter 181 in a vacuum. In FIG. 2, the area of normal atmospheric pressure and the area of the vacuum are divided by a dotted line. A first seal member 188, disposed at the interface between the area of the normal atmospheric pressure and the area of the vacuum, is used to maintain the vacuum. The first seal member 188 is fixed by a hexagonal nut 185.

Specifically, in the evaporation chamber 11, the shutter 181 connects to the shaft 183 via a connecting piece 182. The shaft 183 connects to the rotation mechanism 190 outside the evaporation chamber 11 through a base 186 disposed on the evaporation chamber 11. A check nut 184 is used to prevent the hexagonal nut 185 from loosening. A second seal member 187, disposed between the base 186 and the shaft 183, is used to maintain the seals' integrity.

The rotation mechanism 190 comprises a channel 191, a fixed member 192, a cylinder 193 for rotating the shaft 183. The first seal member 188 is disposed between the channel 191 and the base 186. The fixed member 192 connects to the channel 191 by plural first screws 194, and it connects to the cylinder 193 by plural second screws 195.

By means of the above construction, the cylinder 193 rotates the shutter 181 through the shaft 183.

However, since the base 186 is only fixed by the hexagonal nut 185, the check nut 184 and the hexagonal nut 185 gradually loosen due to the vibration of the shaft 183 caused by the rotation of the shutter 181. As a result, the position of the channel 191 cannot be maintained so that the shift of shutter 181 and subsequent leakage of the vacuum may occur.

When the shutter 181 shifts, the particles, produced during the pre-melting of the source 15, can ascend with the vapor because the shutter 181 can not cover the source 15 completely. In addition, before the source 15 is completely pre-melted, its deposition rate is unstable. At this time, if the vapor, produced by the source 15, is deposited on the wafer 13, the thickness of the film on the wafer 13 may be uneven.

Furthermore, when the hexagonal nut 185 loosens, the vacuum in the evaporation chamber 11 becomes compromised. Hence, the electron beam evaporator 10 can not satisfy the requested condition of the evaporation deposition process. As a result, the whole evaporator 10 must be shut down and can not produce.

### SUMMARY OF THE INVENTION

In view of the disadvantages of the aforementioned conventional shutter rotation device, the invention provides a shutter rotation device that prevents its shutter from shifting.

Accordingly, the invention provides a shutter rotation device. It is adapted for an electric beam evaporator that is provided with a frame. The shutter rotation device comprises a rotation mechanism and a first fixed member that connects the frame to the rotation mechanism.

Furthermore, the rotation mechanism comprises a second fixed member connecting to the first fixed member.

Furthermore, the shutter rotation device further comprises plural first screws and plural second screws. The first screws are used to connect the first fixed member to the frame, and the second screws are used to connect the first fixed member to the second fixed member.

Furthermore, the invention provides a shutter rotation device. It is adapted for an electric beam evaporator. The shutter rotation device comprises a rotation mechanism and a first fixed member that connects to the rotation mechanism. The first fixed member is used to stabilize the rotation mechanism.

### BRIEF DESCRIPTION OF THE DRAWINGS

The invention is hereinafter described in detail by reference to the accompanying drawings in which:

FIG. 1 is a schematic view depicting an electric beam evaporator;

FIG. 2 is a schematic view depicting a conventional shutter rotation device; and

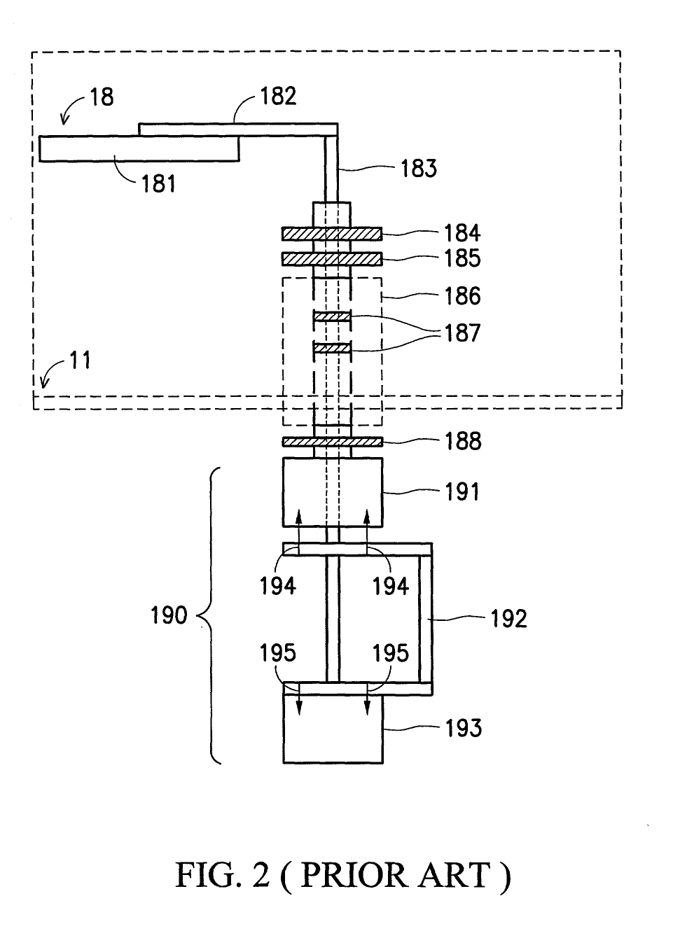

FIG. 3 is a schematic view depicting a shutter rotation device of this invention.

### DETAILED DESCRIPTION OF THE INVENTION

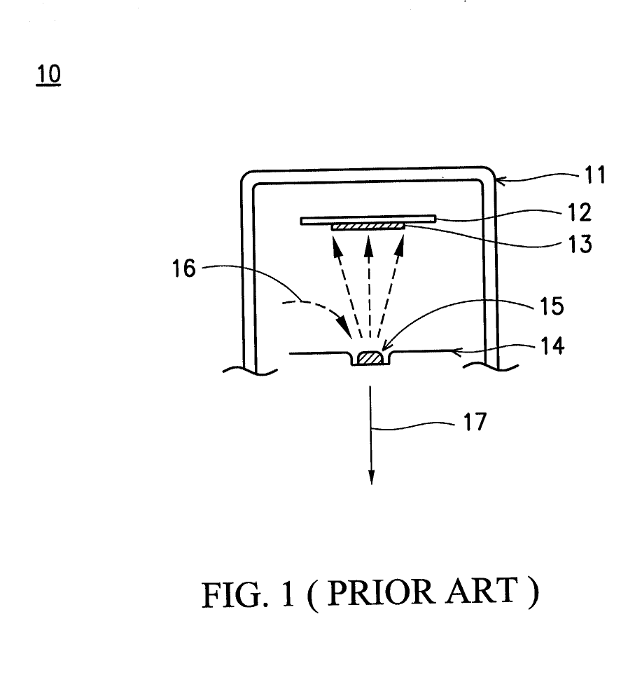

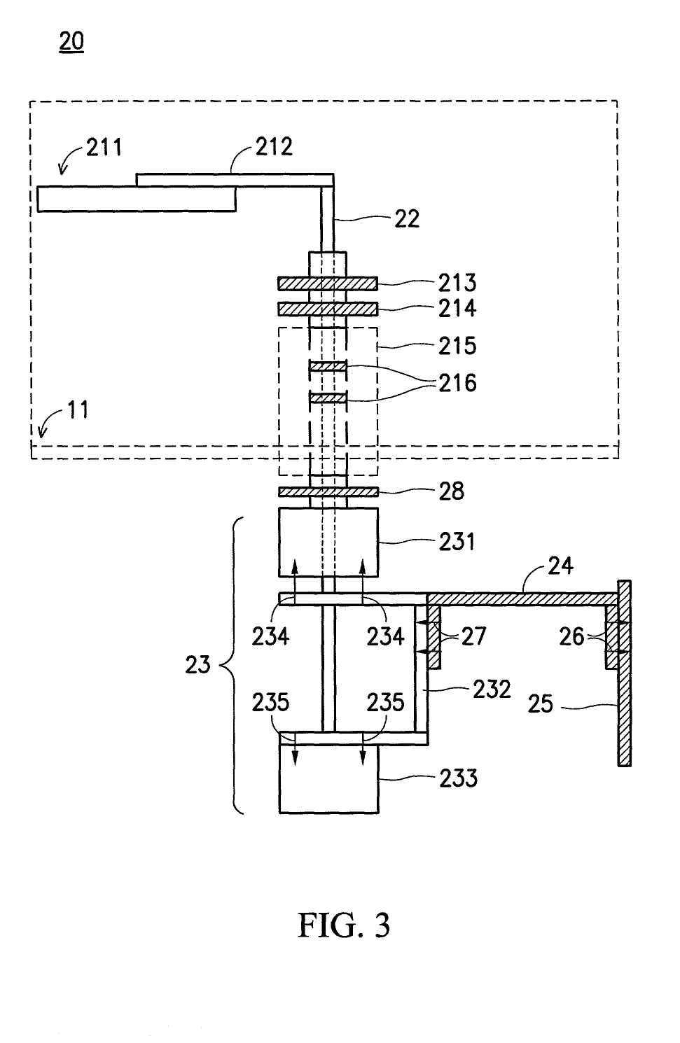

Referring to FIG. 3, the basic construction of a shutter rotation device 20 of this invention is the same with a conventional shutter rotation device 18. The shutter rotation device 20 is disposed inside an electric beam evaporator 10 that is provided with a frame 25 and shown in FIG. 1.

As shown in FIG. 3, the shutter rotation device 20 is provided with a rotation mechanism 23 in normal atmospheric pressure, and it is provided with a shutter 211, a connecting piece 212, a check nut 213, a hexagonal nut 214, a base 215 and a second seal member 216 in vacuum. In FIG. 3, the area of normal atmospheric pressure and the area of the vacuum are divided by a dotted line. A check nut 213 is used to prevent the hexagonal nut 214 from loosening.

The rotation mechanism 23 comprises a channel 231, a second fixed member 232, a cylinder 233 for rotating the rotation mechanism 23, plural third screws 234 and plural fourth screws 235. The second fixed member 232 connects to the channel 231 by the third screws 234, and it connects to the cylinder 233 by the fourth screws 235.

By means of the hexagonal nut 214, the first seal member 28 is disposed between the channel 231 and the base 215, and is used to prevent the vacuum inside the evaporation chamber 11 from becoming leaked. The shaft 22 connects to the shutter 211 by the connecting piece 212, and it connects to the cylinder 233 through the base 215. The second seal member 216, disposed between the base 215 and the shaft 22, is used to maintain their seal condition.

The mounting manner of the elements of this invention is the same with the conventional device; therefore, their description is omitted. The difference between this invention and the conventional device is that a first fixed member 24 is additionally disposed and used to connect the frame 25 to the rotation mechanism 23.

Furthermore, the shutter rotation device 20 further comprises plural first screws 26 and plural second screws 27. The first screws 26 are used for connecting the first fixed member 24 to the frame 25, and the second screws 27 are used for connecting the first fixed member 24 to the second fixed member 232.

By means of adding the first fixed member 24, the position of the rotation mechanism 23 will not shift even if the hexagonal nut 214 loosens. Therefore, the shutter 211 will not shift, and the position of the seal member 28, 216 can be maintained. As a result, the vacuum inside the evaporation chamber 11 can be maintained.

While the invention has been particularly shown and described with reference to a preferred embodiment, it will be readily appreciated by those of ordinary skill in the art that various changes and modifications may be made without departing from the spirit and scope of the invention. It is intended that the claims be interpreted to cover the disclosed embodiment, those alternatives which have been discussed above, and all equivalents thereto.

What is claimed is:

1. A shutter rotation device adapted for an electric beam evaporator, wherein the electric beam evaporator is provided with a frame, and the shutter rotation device comprises a rotation mechanism, characterized in that:
the shutter rotation device further comprises a first fixed member to connect the frame to the rotation mechanism.

2. The shutter rotation device as claimed in claim 1, wherein the rotation mechanism comprises a second fixed member connecting to the first fixed member.

3. The shutter rotation device as claimed in claim 2, further comprising:
a plurality of first screws for connecting the first fixed member to the frame; and
a plurality of second screws for connecting the first fixed member to the second fixed member.

4. A shutter rotation device adapted for an electric beam evaporator, comprising:
a rotation mechanism; and
a first fixed member, connecting to the rotation mechanism, for stabilizing the rotation mechanism.

5. The shutter rotation device as claimed in claim 4, wherein the rotation mechanism comprises a second fixed member connecting to the first fixed member.

6. The shutter rotation device as claimed in claim 5, wherein the electric beam evaporator is provided with a frame, and the shutter rotation device further comprises:
a plurality of first screws for connecting the first fixed member to the frame; and
a plurality of second screws for connecting the first fixed member to the second fixed member.
